(19) United States
(12) Patent Application Publication
(10) Pub. No.: US 2026/0164561 A1
(43) Pub. Date: Jun. 11, 2026

(54) PRINTED CIRCUIT BOARD

(71) Applicant: SAMSUNG ELECTRO-MECHANICS CO., LTD., Suwon-si (KR)

(72) Inventors: Kyeong Yub JUNG, Suwon-si (KR); Ki Ran PARK, Suwon-si (KR); Yong Duk LEE, Suwon-si (KR); Kwang Jin KIM, Suwon-si (KR); Jin Oh PARK, Suwon-si (KR); Sung HAN, Suwon-si (KR); Seong Hun NA, Suwon-si (KR); Sang Ik CHO, Suwon-si (KR)

(73) Assignee: SAMSUNG ELECTRO-MECHANICS CO., LTD., Suwon-si (KR)

(21) Appl. No.: 19/317,022

(22) Filed: Sep. 2, 2025

(30) Foreign Application Priority Data
Dec. 10, 2024 (KR) 10-2024-0182797

(51) Int. Cl. H05K 1/18; H05K 1/09; H05K 1/11

(52) U.S. Cl. CPC H05K 1/185; H05K 1/115; H05K 1/09; H05K 2201/09827

(57) ABSTRACT

A printed circuit board includes an insulating body, a cavity penetrating a portion of the insulating body and having a bottom surface, a plurality of wiring layers respectively disposed within the insulating body, an electronic component at least partially disposed within the cavity, and an encapsulant encapsulating at least a portion of each of the insulating body and the electronic component and filling at least a portion of the cavity.

### CROSS-REFERENCE TO RELATED APPLICATION(S)

This application claims benefit of priority to Korean Patent Application No. 10-2024-0182797 filed on Dec. 10, 2024 in the Korean Intellectual Property Office, the disclosure of which is incorporated herein by reference in its entirety.

### TECHNICAL FIELD

The present disclosure relates to a printed circuit board that may be used as a package substrate, or the like.

Currently, the semiconductor package market is facing fierce competition in packaging technology, related to high-performance computing, used to process and store data as the amount of data usage in data centers, automotive electronics, AI solutions, and the like increases explosively. However, as the performance of semiconductors increases, transistor density and power density increase, problems such as cost, process complexity, and fab investment in the semiconductor design and manufacturing process are occurring significantly. To solve these issues, efforts are being made to reduce the limitations occurring in the entire semiconductor process through innovation in packaging technology. For example, various packaging platforms such as 2.nD, 2.5D, and 3D are being introduced, and are each developing its own advanced packaging technology. In detail, as the number of HBMs increases due to the improvement in GPU and AI performance, technologies for embedding wiring bridges into package substrates as solutions for large substrates and die-to-die connections are being actively developed. Meanwhile, the currently disclosed wiring bridge embedding technology typically attaches the wiring bridge inside the substrate using DAF, or the like, and thus electrical connection is possible only through the upper side of the wiring bridge. In this case, it may be somewhat disadvantageous in terms of power characteristics as well as signal transmission loss.

### SUMMARY

Some aspects of the present disclosure is to provide a printed circuit board in which stability and reliability may be secured while allowing electrical connection to the lower side and connecting at a fine pitch when embedding electronic components such as wiring bridges.

Some aspects of the present disclosure is to provide a printed circuit board in which manufacturing costs may be efficiently managed while improving performance and efficiency of a semiconductor package.

According to some aspects of the present disclosure, a blind-shaped cavity having a bottom surface is formed in a multilayer substrate structure, an electronic component such as an wiring bridge is disposed and embedded in the cavity, and the electronic component is connected to a pad and the like, exposed on the bottom surface of the cavity, using a connecting member. At this time, the pad and the like exposed on the bottom surface of the cavity is formed as a metal layer containing a nanotwin metal.

According to some aspects of the present disclosure, a printed circuit board includes an insulating body, a cavity penetrating a portion of the insulating body and having a bottom surface, a plurality of wiring layers respectively disposed within the insulating body, an electronic component at least partially disposed within the cavity, and an encapsulant encapsulating at least a portion of each of the insulating body and the electronic component and filling at least a portion of the cavity. One wiring layer among the plurality of wiring layers may include a pad at least partially exposed from the insulating body through the cavity, the electronic component is connected to the pad via a connecting member, and the pad includes a nanotwin metal.

According to some aspects of the present disclosure, a printed circuit board includes a plurality of insulating layers, a plurality of wiring layers disposed within the plurality of insulating layers respectively, a cavity penetrating through at least one of the plurality of insulating layers and exposing at least a portion of one wiring layer among the plurality of wiring layers from the plurality of insulating layers, an wiring bridge at least partially disposed within the cavity, and an encapsulant disposed on the plurality of insulating layers, covering at least a portion of the wiring bridge, and filling at least a portion of the cavity. The one wiring layer includes nanotwin copper, and the exposed at least a portion of the one wiring layer is connected to the wiring bridge via a connecting member.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a cross-sectional view schematically illustrating an enlarged view of R region of the printed circuit board of FIG. 3; and

FIGS. 5 and 6 are cross-sectional views schematically illustrating a manufacturing example of the printed circuit board of FIG. 3.

### DETAILED DESCRIPTION

Hereinafter, the present disclosure will be described with reference to the attached drawings. In the drawings, the shapes and sizes of elements may be exaggerated or reduced for clearer explanation.

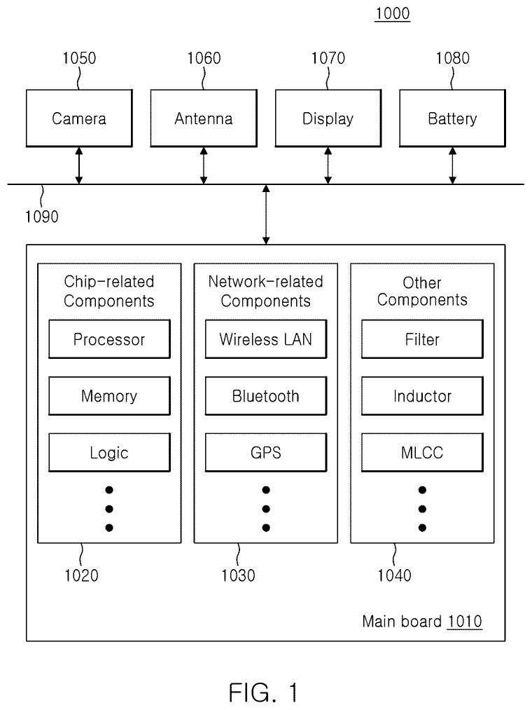

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may also be combined with each other. The chip-related component 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access +(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, and the like. In addition, other components 1040 may also be combined with the chip related components 1020 and/or the network related components 1030.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like, but are not limited thereto. These other electronic components may be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, these other electronic components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, a server, or the like. However, the electronic device 1000 is not limited thereto, but may be any other electronic device processing data.

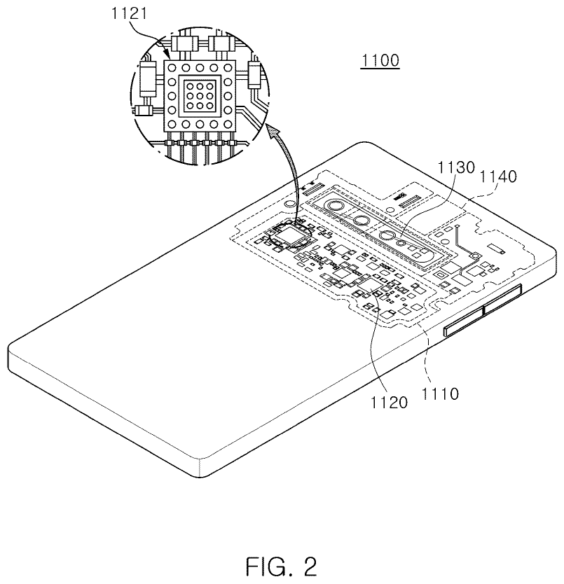

FIG. 2 is a schematic perspective view illustrating an example of an electronic device.

Referring to the drawing, the electronic device may be, for example, a smartphone 1100. A motherboard 1110 may be accommodated in the smartphone 1100, and various electronic components 1120 may be physically or electrically connected to the motherboard 1110. In addition, other components that may or may not be physically or electrically connected to the motherboard 1110, such as a camera module 1130 and/or a speaker 1140, may be accommodated. Some of the electronic components 1120 may be the chip related components described above, for example, a component package 1121, but are not limited thereto. The component package 1121 may be in the form of a printed circuit board on which electronic components including active components and/or passive components are surface-mounted. Alternatively, the component package 1121 may be in the form of a printed circuit board on which active components and/or passive components are built-in. Meanwhile, the electronic device is not necessarily limited to the smartphone 1100, but may be other electronic devices as described above.

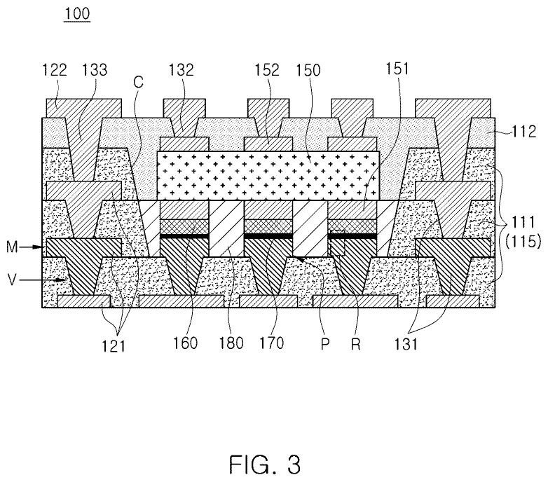

FIG. 3 is a cross-sectional view schematically illustrating an example of a printed circuit board.

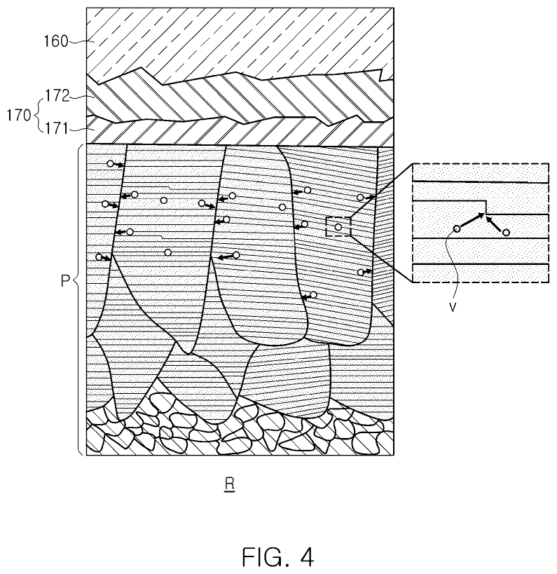

FIG. 4 is a cross-sectional view schematically illustrating an enlarged view of an R region of the printed circuit board of FIG. 3.

Referring to the drawing, a printed circuit board 100 according to some embodiments may include an insulating body 115, a cavity (C) penetrating a portion of the insulating body 115 and having a bottom surface, a plurality of wiring layers 121 disposed within the insulating body 115, a plurality of via layers 131 each disposed within the insulating body 115 and each connected to at least one of the plurality of wiring layers 121, an electronic component 150 at least a portion of which is disposed within the cavity (C), and an encapsulant 112 covering at least a portion of each of the insulating body 115 and the electronic component 150 and filling at least a portion of the cavity (C). Among the plurality of wiring layers 121, at least a portion of one wiring layer (M) may be exposed from the insulating body 115 through the cavity (C). At least the exposed portion may include a pad (P). The electronic component 150 may be connected to the pad (P) through a connecting member 160. One wiring layer (M) among the plurality of wiring layers 121 and one via layer 131 among the plurality of via layers 131 connected thereto may each include a nanotwin metal, for example, nanotwin copper. The pad (P) included in one wiring layer (M) may also include a nanotwin metal, for example, nanotwin copper. The connecting member 160 may include solder. An intermediate layer 170 may be disposed between the pad (P) and the connecting member 160.

In this way, in the printed circuit board 100 according to some embodiments, an electronic component 150 disposed and embedded in a cavity (C) may be electrically, downwardly connected to one wiring layer (M) among a plurality of wiring layers 121, thereby preventing signal transmission loss and having a more advantageous structure in terms of power characteristics. At this time, since the pad (P) of one wiring layer (M) connected to a connecting member 160 such as solder may include a nanotwin metal, for example, nanotwin copper, the occurrence or growth of Kirkendall void, or the like may be suppressed, and reliability improvement may be expected. For example, such a nanotwin copper structure may have a plurality of triple points where twin boundaries and grain boundaries meet, which may hinder the movement of vacancies (v), thereby suppressing the occurrence or growth of Kirkendall voids, as described above. Accordingly, when a plurality of first electrodes 151 having a fine pitch, disposed on the lower side of the electronic component 150, are respectively thermocompression-bonded to a plurality of pads (P) through a plurality of connecting members 160, better stability and reliability may be secured. For example, reliability may be secured by preventing the occurrence of voids or cracks in the intermediate layer 170 or an intermetallic compound (IMC) layer included therein through the above-described effect. Meanwhile, an insulating material 180 may be further disposed in the lower side of the cavity (C) to fill at least a portion of the lower side of the cavity (C) and to cover respective at least portions of the plurality of first electrodes 151, the plurality of pads (P), and the plurality of connecting members 160, thereby further improving the stability and reliability described above.

Meanwhile, the printed circuit board 100 according to some embodiments may further include a build-up wiring layer 122 disposed on an encapsulant 112, a plurality of first build-up vias 132 penetrating at least a portion of the encapsulant 112 and respectively connecting at least a portion of the build-up wiring layer 122 to a plurality of second electrodes 152 disposed on an upper side of an electronic component 150, and one or more second build-up vias 133 collectively penetrating respective at least portions of the encapsulant 112 and the insulating body 115 and respectively connecting at least another portion of the build-up wiring layer 122 to an uppermost wiring layer 121 among the plurality of wiring layers 121. The electronic component 150 may be an wiring bridge in which a plurality of first electrodes 151 are disposed therebelow and a plurality of second electrodes 152 are disposed thereon. Inside the electronic component 150, for example, inside the wiring bridge, various types of circuits and vias may be disposed to provide electrical connection paths between the plurality of first electrodes 151, electrical connection paths between the plurality of second electrodes 152, and/or electrical connection paths between the plurality of first and second electrodes 151 and 152. The wiring bridge may include a silicon wiring bridge, but is not limited thereto, and may of course include an organic substrate including high-density wirings, for example, an organic wiring bridge.

In this way, in the printed circuit board 100 according to some example embodiments, the electronic component 150 may be electrically connected to the plurality of wiring layers 121 and/or the build-up wiring layer 122 respectively on both the lower side and the upper side through the plurality of first and second electrodes 151 and 152. Therefore, for example, in the case where the electronic component 150 includes an wiring bridge as described above, the printed circuit board 100 according to some embodiments may prevent signal transmission loss, have a more advantageous structure in terms of power characteristics, and may be used as an wiring bridge embedding package substrate that may enable die-to-die wiring in a 2.1D form. In this case, the performance and efficiency of the semiconductor package may be improved while also efficiently managing the manufacturing cost. In addition, as described above, excellent stability and reliability may be obtained.

Meanwhile, if necessary, a plurality of insulating layers, a plurality of wiring layers, a plurality of via layers, and the like may be further disposed in the lower side of the insulating body 115 of the printed circuit board 100 according to some embodiments. For example, the structure of the printed circuit board 100 according to some embodiments may be applied to the upper side area of a multilayer core board including a core layer or a multilayer core board having a coreless structure. For example, the structure of the printed circuit board 100 according to some embodiments may be applied to at least a portion of various types of multilayer board structures.

Hereinafter, components of the printed circuit board 100 according to some embodiments will be described in more detail with reference to the drawings.

The insulating body 115 may include a plurality of insulating layers 111. A plurality of wiring layers 121 and a plurality of via layers 131 may be respectively disposed within the plurality of insulating layers 111. The plurality of insulating layers 111 and the encapsulant 112 may each include an organic insulating material. As the organic insulating material, a thermosetting resin such as an epoxy resin, a thermoplastic resin such as a polyimide, or a material in which these insulating resins are mixed with an inorganic filler such as silica, or a resin impregnated into a core material such as glass fiber together with an inorganic filler, for example, an insulating material such as prepreg, Ajinomoto Build-up Film (ABF), Photoimageable Dielectric (PID), Resin Coated Copper (RCC), or the like may be used, but the present disclosure is not limited thereto. The number of layers of the plurality of insulating layers 111 is not particularly limited. The plurality of insulating layers 111 may be integrated with each other so that their boundaries may not be distinguished from each other with the naked eye, but may be distinguished from each other using a scanning electron microscope (SEM).

The plurality of wiring layers 121 and the build-up wiring layer 122 may each include a metal. The metal may include at least one selected from the group consisting of copper (Cu), aluminum (Al), silver (Ag), tin (Sn), gold (Au), nickel (Ni), lead (Pb), titanium (Ti), and alloys thereof. In detail, copper (Cu) may be included. The plurality of wiring layers 121 and the build-up wiring layer 122 may each include a seed layer and a metal layer formed by plating on the seed layer. The seed layer may include a rolled copper foil or an electrolytic copper foil of Resin Clad Copper (RCC). Alternatively, the seed layer may be formed by electroless copper plating or electroless nickel plating, and may also be formed by electrolytic nickel plating. The metal layer may be formed by electrolytic plating, and alternatively, may be formed by plating for forming nanotwin copper. The plurality of wiring layers 121 and the build-up wiring layer 122 may each perform various functions according to the design of the corresponding layer, and for example, may include a ground pattern, a power pattern, a signal pattern, and the like. These patterns may include lines, traces, planes, pads, and the like, respectively.

The plurality of via layers 131 may include connection vias, respectively. The connection via of each of the plurality of via layers 131 and the first and second build-up vias 132 and 133 may include a metal, and the metal may include at least one selected from the group consisting of copper (Cu), aluminum (Al), silver (Ag), tin (Sn), gold (Au), nickel (Ni), lead (Pb), titanium (Ti), and alloys thereof, or the like, and in detail, may include copper (Cu). The connection via of each of the plurality of via layers 131 and the first and second build-up vias 132 and 133 may each include a seed layer formed on a wall surface of a through-hole formed in a wall surface of each via hole, and a metal layer formed by plating on the seed layer. The seed layer may be formed by electroless copper plating or electroless nickel plating, and may also be formed by electrolytic nickel plating. The metal layer may be formed by electrolytic plating, alternatively by plating for forming nanotwin copper. Respective connection vias of the plurality of via layers 131 and the first and second build-up vias 132 and 133 may perform various functions according to the design, and for example, may include ground vias, power vias, signal vias, and the like. Each of the connection vias of the plurality of via layers 131 and the first and second build-up vias 132 and 133 may each have a substantially tapered shape. Each of the connection vias of the plurality of via layers 131 and the first and second build-up vias 132 and 133 may be plural.

One wiring layer (M) of the plurality of wiring layers 121 and one via layer (V) of the plurality of via layers 131 may each include a nanotwin metal, in more detail, nanotwin copper, as described above. For example, a pad (P) included in one wiring layer (M) may include a nanotwin metal, in more detail, nanotwin copper. The nanotwin copper may include a plurality of columnar grains, and at least some of the plurality of columnar grains may include nanotwins. A metal layer including the nanotwin copper may be formed on a seed layer. The seed layer may include copper, nickel, or the like, which may be used for a printed circuit board, for example, a package substrate, and may include, for example, an electrolytic copper foil, a rolled copper foil, an electrolytic copper layer, an electroless copper layer, an electrolytic nickel layer, and/or an electroless nickel layer. In this case, the seed layer may include a crystal structure that is not oriented preferentially on the (111) plane, such as a random orientation, a crystal structure that is oriented preferentially on the (200) plane, and/or a crystal structure that is oriented preferentially on the (220) plane. For example, when the crystal orientation of the seed layer is measured and analyzed using Selected Area Electron Diffraction (SAED), ring patterns corresponding to the (111) plane and other (hkl) planes may appear with similar intensities. In such cases, it is difficult to conclude that the (111) plane is preferentially oriented. On the other hand, if the (111) plane is strongly oriented, the (111) plane may appear in a partial ring shape or a dot shape, and the other (hkl) planes may appear in a partial ring shape or the like with relatively low intensity. In this way, when the seed layer includes a crystal structure that is not preferentially oriented in the (111) plane, the [111] direction of at least one columnar grain including the nanotwins of the nanotwin copper included in the metal layer may be tilted at an angle (θ) of more than 0 degree and 25 degrees or less with respect to the growth direction. In this case, the stability and reliability may be improved more effectively. The metal layer may have 80% or more but less than 100% of the nanotwin copper in the (111) plane on the cross-section, and 90% or more but less than 100% on the surface. In addition, the metal layer may have a thickness of about 1 μm to 10 μm, or about 1 μm to 5 μm, and the size of at least one columnar grain including the nanotwins of the nanotwin copper included therein may also be about 1 μm to 10 μm, or about 1 μm to 5 μm. A transition layer may be disposed in the boundary region between the metal layer and the seed layer, and the transition layer may include a portion of the seed layer and a portion of the initial growth layer of the metal layer. The transition layer may be formed with a thickness within 20% of the thickness of the metal layer, but is not limited thereto.

On the other hand, a randomly oriented crystal structure may mean a state in which crystal grains in a polycrystalline metal or thin film structure are not aligned in a specific direction but are randomly distributed in all directions. This may occur when respective crystal grains in the metal structure are arranged independently of each other and no preferential orientation appears. For example, a preferential orientation of a specific plane may not appear, and the directions of all crystal grains may be independently distributed. This may be measured using X-ray diffraction (XRD), pole figure, Selected Area Electron Diffraction (SAED), Electron Backscatter Diffraction (EBSD), or the like. For example, in X-ray diffraction (XRD) data, the peak intensity of each diffraction plane may roughly match or be similar to the relative intensity ratio in an ideal polycrystalline sample. To quantitatively evaluate this, the texture coefficient may be calculated, and the texture coefficients of all planes may have values approximately close to 1. Alternatively, the intensity may be uniformly distributed in a pole figure. Alternatively, in electron diffraction (SAED or EBSD), the orientation may be distributed in various directions, and no specific direction may be dominant.

Also, a crystal structure with a preferred orientation on the (200) plane may mean a state in which a specific crystal plane, the (200) plane, is preferred or primarily aligned over other planes in a polycrystalline metal or thin film structure. This may occur when a lattice plane represented by the Miller index (200) in a metal crystal structure is preferentially grown or oriented by specific process conditions, energy states, or interactions with a substrate. This may be measured using X-ray diffraction (XRD), pole figures, selected area electron diffraction (SAED), electron backscatter diffraction (EBSD), or the like. For example, the preferred orientation of the (200) plane may be confirmed through the fact that the intensity of the (200) peak is relatively more prominent than that of other peaks in X-ray diffraction (XRD) data. To quantitatively evaluate this, the texture coefficient may be calculated, and if the texture coefficient of the (200) plane is relatively large compared to other planes, for example, 1.5 or more, it may be determined that the (200) plane has a preferred orientation. Alternatively, the orientation may be confirmed by analyzing the diffraction radius and intensity of the (200) plane in the pole figure. Alternatively, the preferred orientation may be confirmed by analyzing the fraction and orientation distribution of crystal grains with the (200) plane orientation in electron diffraction (SAED or EBSD).

In addition, a crystal structure with a preferred orientation on the (220) plane may mean a state in which a specific crystal plane, the (220) plane, is preferred or primarily aligned over other planes in a polycrystalline metal or thin film structure. This may occur when the lattice plane represented by the Miller index (220) in the metal crystal structure is preferentially grown or oriented due to specific process conditions, energy states, or interactions with the substrate. This may be measured using X-ray diffraction (XRD), pole figure, selected area electron diffraction (SAED), electron backscatter diffraction (EBSD), or the like. For example, in X-ray diffraction (XRD) data, the preferred orientation of the (220) plane may be confirmed through the fact that the intensity of the (220) peak is relatively more prominent than that of other peaks. To quantitatively evaluate this, the texture coefficient may be calculated, and if the texture coefficient of the (220) plane is relatively large compared to other planes, for example, 1.5 or more, it may be determined that the (220) plane has a preferred orientation. Alternatively, the orientation may be confirmed by analyzing the diffraction radius and intensity of the (220) plane in the pole figure. Alternatively, the fraction and orientation distribution of crystal grains having a (220) plane orientation may be analyzed in electron diffraction (SAED or EBSD) to confirm the preferred orientation.

The electronic component 150 may include various types of active elements and/or passive elements. For example, the electronic component 150 may include various types of integrated circuit dies or semiconductor chips. In addition, the electronic component 150 may include an wiring bridge. The wiring bridge may include a silicon wiring bridge, but is not limited thereto, and may of course include an organic substrate including a high-density wiring, for example, an organic wiring bridge. A plurality of first electrodes 151 may be disposed on the lower surface of the electronic component 150, and a plurality of second electrodes 152 may be disposed on the upper surface of the electronic component 150. Inside the electronic component 150, various types of circuits and vias may be disposed to provide electrical connection paths between the plurality of first electrodes 151, electrical connection paths between the plurality of second electrodes 152, and/or electrical connection paths between the plurality of first and second electrodes 151 and 152.

The first and second electrodes 151 and 152 may include a metal. The metal may include at least one selected from the group consisting of copper (Cu), aluminum (Al), silver (Ag), tin (Sn), gold (Au), nickel (Ni), lead (Pb), titanium (Ti) and alloys thereof. In detail, the metal may include copper (Cu), but is not limited thereto. The first and second electrodes 151 and 152 may each have a micro bump structure. The first and second electrodes 151 and 152 may each have a structure in which a pad and a micro bump are combined. The first and second electrodes 151 and 152 may each be plural.

The connecting member 160 may include a conductive material, for example, solder. The solder may include tin (Sn), which is a low melting point metal. For example, the solder may include a tin(Sn)-silver(Ag)-copper(Cu) alloy, but is not limited thereto. The connecting member 160 may be in the form of a ball or bump. The connecting member 160 may be plural.

The intermediate layer 170 may include an intermetallic compound (IMC) layer formed by reflow after solder bumps are formed on the surface treatment layer formed on the pad (P). The intermediate layer 170 may be composed of multiple layers, and may include, for example, one or more of the Cu₃Sn layer 171 and the Cu₆Sn₅ layer 172, but is not limited thereto. Meanwhile, the surface treatment layer may be formed using various methods and materials as described below.

The insulating material 180 may provide electrical insulation, thermal stability, and mechanical stability. The insulating material 180 may include, but is not limited to, a non-conductive film (NCF), and may also include, in addition, a non-conductive adhesive (NCA), a polyimide film, a silicone-based adhesive or film, an ultraviolet-curable film or adhesive, a heat-melting adhesive film, a polyurethane adhesive, a thermoplastic polymer, or the like.

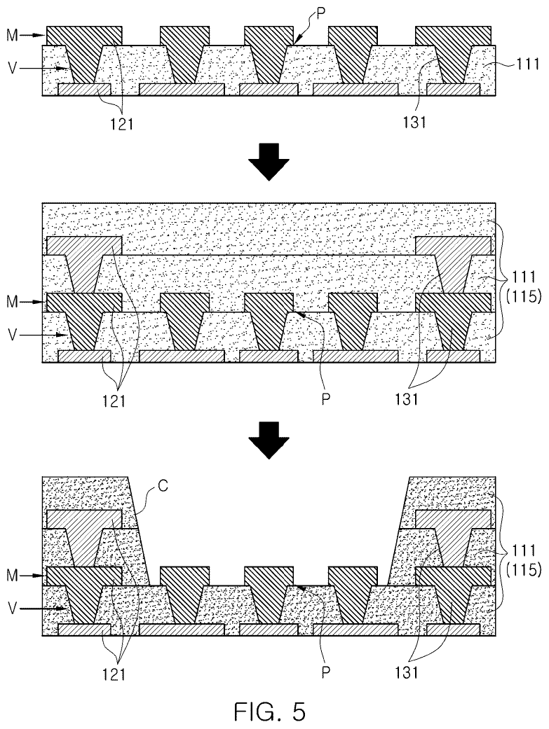

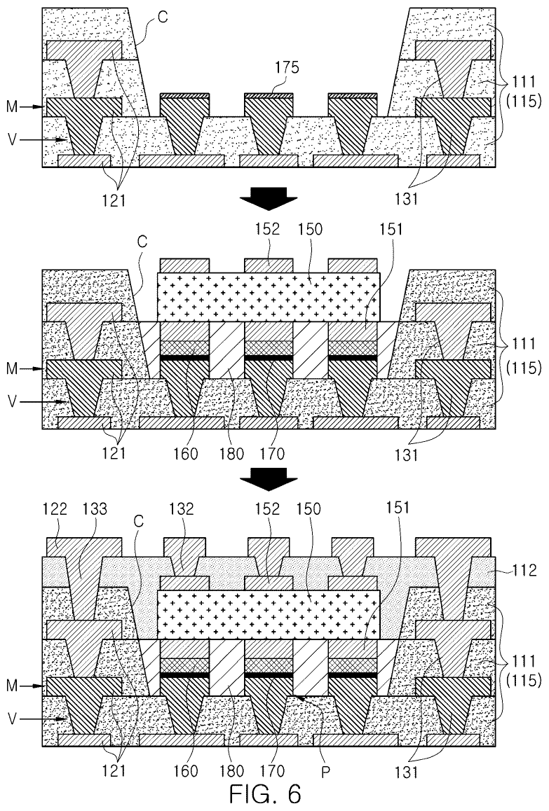

FIG. 5 and FIG. 6 are process cross-sectional views schematically illustrating an example of manufacturing a printed circuit board of FIG. 3.

Referring to FIG. 5, first, a first wiring layer 121 may be formed by a circuit formation process, or the like, a first insulating layer 111 covering the same may be formed by an insulating material lamination process, or the like, a via hole penetrating the first insulating layer 111 may be formed by a laser processing process, or the like, and a first via layer 131 and a second wiring layer 121 may be formed by a circuit formation process, or the like. Meanwhile, the first via layer 131 and the second wiring layer 121 may be a via layer (V) and an wiring layer (M) including a nanotwin metal, such as nanotwin copper. These via layer (V) and wiring layer (M) may be formed by, for example, a seed layer forming process, such as electroless copper plating or electroless nickel plating, and a plating process for forming a nanotwin metal layer on the seed layer, for example, by a plating process for forming nanotwin copper. The wiring layer (M) may be formed to include a plurality of pads (P) having a fine pitch for component mounting. Next, a plurality of insulating layers 111, a plurality of wiring layers 121, and a plurality of via layers 131 may be formed by a build-up process, or the like. The plurality of insulating layers 111 may form an insulating body 115. Next, a blind-shaped cavity (C) may be formed by, for example, blast processing or the like. The plurality of pads (P) may be exposed through the cavity (C). The plurality of pads (P) may be used as a stopper layer for blast processing.

Referring to FIG. 6, next, a surface treatment layer 175 may be formed on the surface of the pad (P). The surface treatment layer 175 may be formed by electrolytic gold plating, electroless gold plating, electroless tin plating, electroless silver plating, electroless nickel plating/substitution gold plating, Organic Solderability Preservative (OSP), Electroless Nickel Immersion Gold (ENIG), Immersion Tin (ImSn), Immersion Silver (ImAg), Direct Immersion Gold (DIG), Hot Air Solder Leveling (HASL), and/or the like. Next, the electronic component 150 may be disposed in the cavity (C), and the electronic component 150 may be mounted using the connecting member 160. For example, a plurality of first electrodes 151 and a plurality of pads (P) may be connected using a plurality of connecting members 160, and then a reflow process may be performed. At this time, an intermediate layer 170 may be formed. Meanwhile, if necessary, an insulating material 180, such as a non-conductive film (NCF), may be formed in the lower side of the cavity (C) by an insulating material lamination process, a coating process or the like. For example, after the electronic component 150 is aligned using the non-conductive film (NCF), a plurality of first electrodes 151 and a plurality of pads (P) may be joined by a thermocompression method using solder. Next, an encapsulant 112 may be formed on the plurality of insulating layers 111 by an insulating material coating, an insulating material lamination process or the like, to cover at least a portion of the electronic component 150 and fill at least a portion of the cavity (C). In addition, a via hole formation process, such as laser processing, and a circuit formation process may be performed on the encapsulant 112, thereby forming a build-up wiring layer 122 and a plurality of first and second build-up vias 132 and 133. Meanwhile, a plurality of first build-up vias 132 may be respectively connected to a plurality of second electrodes 152, thereby providing a fine pitch.

Through a series of processes, a printed circuit board 100 according to the above-described example may be manufactured. Other descriptions may be substantially the same as those described in the printed circuit board 100 according to the above-described example. It goes without saying that the contents described in the manufacturing example may be substantially equally applied to the printed circuit board 100 according to the above-described example.

As set forth above, when embedding electronic components such as wiring bridges, a printed circuit board capable of electrically connecting to the lower side and securing stability and reliability while being able to connect at a fine pitch may be provided.

In addition, a printed circuit board in which manufacturing costs may be efficiently managed while improving performance and efficiency of a semiconductor package may be provided.

In the present disclosure, the expression “covering” may include a case of covering at least a portion as well as a case of covering the whole, and may also include a case of directly covering as well as a case of indirectly covering. In addition, the expression “filling” may include not only a case of completely filling, but also a case of at least partially filling, and may also include a case of approximately filling, and for example, may include a case where some gaps or voids are present. In addition, the expression “surrounding” may include not only the case of completely surrounding, but also the case of partially surrounding and the case of roughly surrounding. In addition, “exposing” may include not only the case of completely exposing, but also the case of partially exposing, and “exposing” may mean exposing from embedding the corresponding configuration. For example, exposing the pad by the cavity may mean exposing the pad from the insulating body, and a surface treatment layer or the like may be further disposed on the exposed pad.

In the present disclosure, it may be determined by including process errors, positional deviations, measurement errors, or the like that occur in the manufacturing process. For example, having a substantially certain shape may include not only having a completely such shape, but also having an approximately such shape. Furthermore, being substantially tapered may include not only a completely tapered shape, but also an approximately tapered shape. For example, it may be determined by the overall shape.

In the present disclosure, the meaning of cross-section may mean a cross-sectional shape when the object is vertically cut, or a cross-sectional shape when the object is viewed from a side-view. In addition, the meaning of “on a plane” may mean a plane shape when the object is horizontally cut, or a plane shape when the object is viewed from a top-view or bottom-view.

In the present disclosure, lower side, lower portion, lower surface, and the like are used to mean a downward direction based on the cross section of the drawing for convenience, and upper side, upper portion, upper surface, and the like are used to mean the opposite direction. However, this is to define the direction for convenience of description, and the scope of the claims is not particularly limited by the description of this direction, of course, and the concept of upper and lower may change at any time.

In the present disclosure, the meaning of being connected is a concept including not only being directly connected but also being indirectly connected through an adhesive layer or the like. In addition, the meaning of being electrically connected is a concept including both physically connected and nonconnected cases. In addition, expressions such as first, second and the like are used to distinguish one component from another, and do not limit the order and/or importance of the components. In some cases, without departing from the scope of rights, the first element may be named a second element, and similarly, the second element may be referred to as the first element.

In the present disclosure, the crystal structure, thickness, and the like may be measured based on the cross-section of the printed circuit board, which is polished or cut, respectively. For example, after obtaining a sample including a cut cross-section, necessary experiments may be conducted based thereon. The cut cross-section may be a vertical cross-section or a horizontal cross-section, and each numerical value may be measured based on the required cut cross-section. Meanwhile, in the case of measuring a numerical value, if the numerical value is not constant, the numerical value may be determined as an average value of values measured at five arbitrary points.

The expression “an (one) example” used in the present disclosure does not mean the same embodiments, and is provided to emphasize and describe different unique characteristics. However, the examples presented above are not excluded from being implemented in combination with features of other examples. For example, even if a matter described in a specific example is not described in another example, it may be understood as a description related to another example, unless there is a description contrary to or contradictory to the matter in the other example.

Terms used in this disclosure are only used to describe an example, and are not intended to limit the disclosure. In this case, singular expressions include plural expressions unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
an insulating body;
a cavity penetrating a portion of the insulating body and having a bottom surface;
a plurality of wiring layers disposed within the insulating body;
an electronic component at least partially disposed within the cavity; and
an encapsulant encapsulating at least a portion of each of the insulating body and the electronic component and filling at least a portion of the cavity,
wherein at least one wiring layer among the plurality of wiring layers includes a pad at least partially exposed from the insulating body through the cavity,
the electronic component is connected to the pad via a connecting member, and
the pad includes a nanotwin metal.

2. The printed circuit board of claim 1, wherein the nanotwin metal includes nanotwin copper.

3. The printed circuit board of claim 2, wherein the nanotwin copper includes a plurality of columnar grains,
wherein at least one of the plurality of columnar grains include nanotwins.

4. The printed circuit board of claim 1, wherein the pad protrudes upwardly of the bottom surface of the cavity.

5. The printed circuit board of claim 1, wherein a lower side of the electronic component is provided with a first electrode disposed thereon, and
the connecting member connects the first electrode and the pad to each other.

6. The printed circuit board of claim 5, wherein the connecting member includes solder, and
the pad and the connecting member are provided with an intermediate layer therebetween,
wherein the intermediate layer includes at least one of a Cu₃Sn layer or a Cu₆Sn₅ layer.

7. The printed circuit board of claim 5, further comprising an insulating material filling at least a portion of a lower side of the cavity and covering respective at least portions of the first electrode, the pad, and the connecting member.

8. The printed circuit board of claim 1, further comprising a plurality of via layers disposed within the insulating body and each connected to at least one of the plurality of wiring layers,
wherein one via layer among the plurality of via layers is connected to one wiring layer, among the plurality of wiring layers, including the pad at least partially exposed.

9. The printed circuit board of claim 8, wherein the one wiring layer and the one via layer connected to each other each includes a seed layer and a metal layer disposed on the seed layer,
wherein the seed layer includes at least one of an electrolytic copper foil, a rolled copper foil, an electrolytic copper layer, an electroless copper layer, an electrolytic nickel layer, and an electroless nickel layer, and
the metal layer includes nanotwin copper.

10. The printed circuit board of claim 9, wherein each of the one wiring layer and the one via layer connected to each other further includes a transition layer disposed in a boundary region between the seed layer and the metal layer.

11. The printed circuit board of claim 8, further comprising:
a build-up wiring layer disposed on the encapsulant;
a first build-up via penetrating at least a portion of the encapsulant and connecting at least a portion of the build-up wiring layer to a second electrode disposed on an upper side of the electronic component; and
a second build-up via collectively penetrating through respective at least portions of the encapsulant and the insulating body, and connecting at least another portion of the build-up wiring layer to an uppermost wiring layer among the plurality of wiring layers.

12. A printed circuit board comprising:
a plurality of insulating layers;
a plurality of wiring layers disposed within the plurality of insulating layers respectively;
a cavity penetrating at least one of the plurality of insulating layers and exposing at least a portion of one wiring layer among the plurality of wiring layers from the plurality of insulating layers;
an wiring bridge at least partially disposed within the cavity; and
an encapsulant disposed on the plurality of insulating layers, covering at least a portion of the wiring bridge, and filling at least a portion of the cavity,
wherein the one wiring layer includes nanotwin copper, and
the exposed at least a portion of the one wiring layer is connected to the wiring bridge via a connecting member.

13. The printed circuit board of claim 12, wherein the nanotwin copper includes a plurality of columnar grains,
wherein at least one of the plurality of columnar grains include nanotwins.

14. The printed circuit board of claim 12, wherein the cavity has a bottom surface, and
the exposed at least a portion of the one wiring layer protrudes upwardly of the bottom surface of the cavity.

15. The printed circuit board of claim 12, wherein the connecting member connects the exposed at least a portion of the one wiring layer to a first electrode disposed on a lower side of the wiring bridge.

16. The printed circuit board of claim 15, wherein the connecting member includes solder, and
the exposed at least a portion of the one wiring layer and the connecting member are provided with an intermediate layer therebetween,
wherein the intermediate layer includes at least one of a Cu₃Sn layer or a Cu₆Sn₅ layer.

17. The printed circuit board of claim 15, further comprising an insulating material filling at least a portion of a lower side of the cavity and covering respective at least portions of the first electrode, the exposed at least a portion of the one wiring layer, and the connecting member.

18. The printed circuit board of claim 12, further comprising:
a plurality of via layers disposed within the plurality of insulating layers respectively, and each connected to at least one of the plurality of wiring layers;
a build-up wiring layer disposed on the encapsulant;
a first build-up via penetrating at least a portion of the encapsulant, and connecting at least a portion of the build-up wiring layer to a second electrode disposed on an upper side of the wiring bridge; and
a second build-up via collectively penetrating respective at least portions of the encapsulant and an uppermost insulating layer of the plurality of insulating layers and connecting another portion of the build-up wiring layer to an uppermost wiring layer of the plurality of wiring layers.
